(19) United States
(12) Patent Application Publication
(10) Pub. No.: US 2009/0296389 A1
(43) Pub. Date: Dec. 3, 2009

(54) LIGHT SOURCE MODULE, RELATED LIGHT BAR AND RELATED LIQUID CRYSTAL DISPLAY

(76) Inventor: Chia-Liang HSU, Yangmei Town (TW)

Correspondence Address: Muncy, Geissler, Olds & Lowe, PLLC, P.O. BOX 1364, FAIRFAX, VA, 22038-1364, US

(21) Appl. No.: 12/475,128

(22) Filed: May 29, 2009

(30) Foreign Application Priority Data
May 30, 2008 (TW) 097120199

(51) Int. Cl. F21V 1/00; H01L 33/00

(52) U.S. Cl. 362/235; 257/98; 257/E33.067

(57) ABSTRACT

A light source module includes a bottom circuit board, a plurality of LED chips disposed on the bottom circuit board, and a sealant covering the LED chips. Each LED chip includes a light-emitting structure and at least a patterned reflecting layer disposed on the light-emitting structure. The patterned reflecting layer can appropriately enhance the brightness of the lateral surface of the LED chip. Thus, the diffuser particles included in the sealant can diffuse light so that the light beams emitted from the lateral surfaces of the LED chips can exit from the light-exiting surface of the light source module. Accordingly, a uniform light distribution of the light source module can be provided.

### TECHNICAL FIELD

The present invention relates to a light source module, especially to the light source module employing a light-emitting diode (LED) as a light source.

### REFERENCE TO RELATED APPLICATION

This application claims the right of priority based on TW application Ser. No. 097120199, filed “May 30, 2008”, entitled “LIGHT SOURCE MODULE, RELATED LIGHT BAR AND RELATED LIQUID CRYSTAL DISPLAY” and the contents of which are incorporated herein by reference.

### BACKGROUND

A light source module can be applied to various kinds of displays and illuminative devices. Taking a Back-Light Unit (BLU) of the display for example, the conventional BLU employs Cold Cathode Fluorescent Lamp (CCFL) as a light source. Referring to FIG. 1 which is a cross-sectional view of a conventional BLU 20, the BLU 20 is located under a display panel 10 and includes a shell 12, a plurality of lamps 14, a diffuser 16, and a reflector 18. The plurality of lamps 14 are parallely arranged in a chamber 22 defined by the shell 12. The reflector 18 reflects light generated from the plurality of lamps 14 upward to enhance the utilization efficiency of light. The diffuser 16 further diffuses the reflected light uniformly. In addition, another diffuser 24 can be located between the BLU 20 and the display panel 10 to enhance light uniformity.

However, CCFL includes several drawbacks like poor color rendering index, high forward voltage, mercury contained, having a spectrum with in ultraviolet region, slow starting speed, a cracky tube, the difficulty in controlling the chromaticity, and so on. Therefore, an LED package has been applied in BLU as a light source recently. The LED package basically includes a cup and an LED chip mounted on the cup. The cup includes two inward connective ends which electrically connect with the LED chip, and two outward connective ends which electrically connect with a controlling device outside. Because the LED package has advantages like small volume, low electricity consumption, high brightness, high color performance, fast reaction speed (operation in high frequency), environmental protection (shock-endurable, uncracky, and recyclable), and fitness for thin products, it is popular in small-dimension liquid crystal displays (LCDs).

Nevertheless, because light-emitting profile of the LED package is close to that of a point light source, the screen where is close to the LED package is brighter and results in non-uniform brightness of the image. To solve the problem mentioned above, the thickness of the BLU is usually increased to provide space for light mixing, or more optical films are added in displays for light mixing and complement. Therefore, not only is the volume of the display increased, but also the cost of manufacturing is increased.

As the idea of using LED as a light source becomes popular, the related technology of applying LED in various sizes of BLU and LED light bar (LB) is getting more important. Accordingly, it is an important issue to provide an LED light source module with great optical efficiency and slim structure.

### SUMMARY

The present application provides a light source module applicable to LCD and LB. The light source module includes good optical efficiency, slim structure, and uniform brightness to solve aforementioned problems.

To achieve aforementioned purposes, the present application provides a light source module including a first print circuit board (PCB), a plurality of LED chips, and a sealant covering the plurality of LED chips. The plurality of LED chips are located on a top surface of the first PCB and electrically connected with the first PCB. Each of the plurality of LED chips includes a light-emitting structure and at least a patterned reflective layer on the light-emitting structure, wherein the patterned reflective layer includes at least an opening and a reflective region. The sealant includes a top surface to become a main surface of light extraction, and a plurality of diffusing particles to diffuse light generated from the LED chips.

To make the aforementioned purposes, characteristics, and advantages easy to be understood, the following description provides preferable embodiments associated with the attached drawings for explanation. However, the following preferable embodiments and drawings are provided for reference and explanation only, not for limiting the present invention.

### BRIEF DESCRIPTION OF THE DRAWINGS

FIG. 1 shows a cross-sectional view of a conventional BLU.

FIG. 2 shows a side view of an LED chip of a first embodiment of the present application.

FIG. 3 and FIG. 4 show schematic views of a patterned reflective layer in accordance one embodiment of the present application.

FIG. 5 and FIG. 6 show side views of the LED chip of a second embodiment and a third embodiment of the present application.

FIG. 7 shows a side view of an LCD of a forth embodiment of the present application.

FIG. 8 shows a schematic view of a BLU of FIG. 7.

FIG. 9 shows a side view of the BLU of a fifth embodiment of the present application.

FIG. 10 and FIG. 11 show schematic views of electrical connection of different kinds of the LED chips adopted in the embodiments of the present application.

FIG. 12 shows a schematic view of an LB of a six embodiment of the present application.

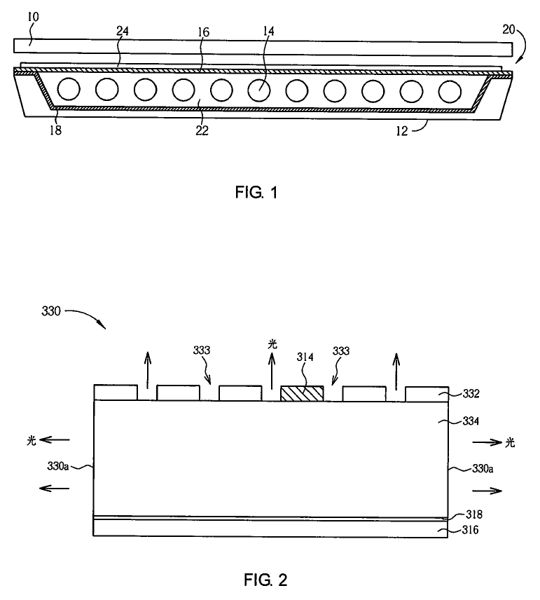

### DETAILED DESCRIPTION

Referring to FIG. 2 which is a side view of an LED chip 330 of a first embodiment, the LED chip 330 includes a light-emitting structure 334, a reflective layer 318, a first electrode 314, a second electrode 316, and a patterned reflective layer 318. The light-emitting structure 334 can include a substrate and a light-emitting stacked layer (not shown), wherein the light-emitting stacked layers at least include an active layer. The first electrode 314 and the second electrode 316 can include conductive materials like metal or alloy. When applying forward voltage to the LED chip 330, the light-emitting structure 334 can emit light to surrounding areas. The reflective layer 318 is located between the light-emitting structure 334 and the second electrode 316. The light originally emitting to the second electrode 316 can be reflected by the reflective layer 318 toward upside or lateral surfaces 330a of the LED chip 330 to enhance brightness of the LED chip 330. In another aspect, lateral light generated from the light-emitting structure 334 can emit toward the lateral surfaces 330a without passing the reflective layer 318 or the patterned reflective layer 332.

The patterned reflective layer 332 includes reflective materials and a plurality of openings 333 which are pervious to light. A portion of the light generated from the light-emitting structure 334 can emit upward through the plurality of openings 333, and another portion of that can be reflected by the patterned reflective layer 332 to emit toward the lateral surfaces 330a. In a preferable embodiment of the present application, the patterned reflective layer 332 preferably allows 5%˜10% of the light of the LED chip 330 to emit outside through the plurality of openings 333, and makes 95%˜90% of that emit outside through the lateral surfaces 330a so as to enable the lateral surfaces 330a to become a main light-emitting surface. In this embodiment, the first electrode 314 and the patterned reflective layer 332 are located on the same horizontal plane, wherein they can be made of the same or different materials. When the first electrode 314 includes opaque materials, it can be deemed as a portion of the patterned reflective layer 332.

Because the brightness of the upside of the conventional LED package is brighter than that of the lateral sides of the conventional LED package, it easily results in non-uniform brightness of the image. Therefore, the present application employs the patterned reflective layer 332 to reflect the light originally emitting toward the upside of the LED chip 330 to the lateral sides thereof. The intensity of the light received at each view angle around the periphery of the LED chip 330 is close so brightness of the upside of the LED chip 330 is not brighter than that of the lateral sides of the LED chip 330 and the LED chip 330 has much uniform brightness. Therefore, when the LED chip 330 is applied to the light source module, it can solve the problem of non-uniform brightness of the light source module without increasing space of the light source module for promoting uniformity of brightness.

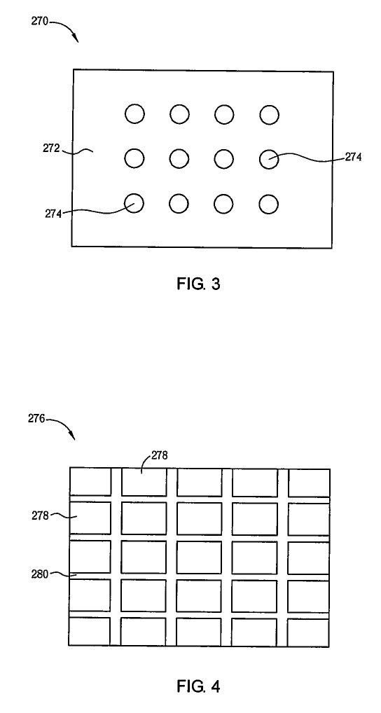

In the present application, materials, patterns, and locations of the patterned reflective layer 332 are not limited by the LED chip 330 as shown in FIG. 2 and can be modified in accordance with the needs of various products. For example, the material of the patterned reflective layer 332 can be In, Sn, Al, Au, Pt, Zn, Ag, Ti, Pb, Ge, Cu, Ni, AuBe, AuGe, AuZn, PbSn, the combination thereof, or Distributed Bragg Reflector (DBR). In a schematic view, a pattern of the patterned reflective layer preferably includes openings distributed uniformly as shown in FIG. 3 and FIG. 4. Referring to FIG. 3, the patterned reflective layer 270 at least includes a reflective region 272 and a plurality of circle openings 274 which are pervious to light. Referring to FIG. 4, the patterned reflective layer 276 includes a plurality of reflective regions 278 and at least a grid opening 280. In the schematic views, the area of the patterned reflective layer 270 occupied by a light-pervious region of the patterned reflective layer 270 is 5% to 20%, preferably 5% to 10%. Namely, the ratio of the area occupied by the reflective region 272 to that occupied by the plurality of light-pervious circle openings is about 19 to 4. So is the ratio of the area occupied by the plurality of reflective regions 278 to that occupied by the grid opening 280. Therefore, the lateral surfaces of the LED chip can become main light-emitting lateral surfaces.

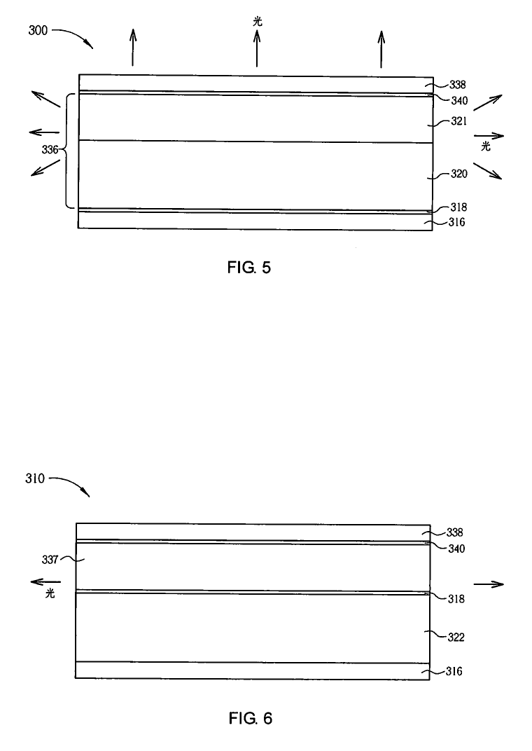

In other embodiments, the patterned reflective layer can be formed between the first electrode and the light-emitting structure. FIG. 5 and FIG. 6 are side views of the LED chips 300 and 310 of a second embodiment and a third embodiment of the present application respectively. The LED chip 300 can include a light-emitting structure 336, a reflective layer 318, a first electrode 338, a second electrode 316, and a patterned reflective layer 340. The light-emitting structure 336 includes a transparent substrate 320 and a light-emitting stacked layer 321, wherein the light-emitting stacked layer 321 at least includes an active layer. The reflective layer 318 is located between the second electrode 316 and the transparent substrate 320. Light of the LED chip 300 can emit out from the light-emitting stacked layer 321. A portion of the light can penetrate the transparent substrate 320 and be reflected out. Therefore, all lateral sides of the light-emitting structure 336 can emit light. In addition, the patterned reflective layer 340 is located between the first electrode 338 and the light-emitting structure 336, and can allow a portion of light emitting upward through the patterned reflective layer 340. The patterned reflective layer 340 can reflect a portion of light generated from the light-emitting structure 336 to balance light-emitting intensity of a top surface and lateral surfaces of the LED chip 300.

Referring to FIG. 6, an LED chip 310 can include a light-emitting stacked layer 337, an opaque substrate 322, a reflective layer 318, a first electrode 338, a second electrode 316, and a patterned reflective layer 340, wherein the light-emitting stacked layer 337 at least includes an active layer. The reflective layer 318 is located between the opaque substrate 322 and the light-emitting stacked layer 337 so light-emitting profile of the LED chip 310 is different from that of the LED chip 300. When light generated from the light-emitting stacked layer 337 emits outside, the light emitting to downside does not penetrate the opaque substrate 322 and is reflected by the reflective layer 318. Therefore, the light of the LED chip 310 gathers on the lateral sides of the light-emitting stacked layer 337 and emits outside.

In the second and third embodiments, when the first electrode 338 is a transparent layer, the first electrode 338 and the second electrode 316 can substantially cover all the top surfaces or bottom surfaces of the LED chips 300 or 310. Otherwise, the first electrode 338 also can include the same pattern as the patterned reflective layer 340 so a portion of light can penetrate the patterned reflective layer 340 and the first electrode 338 and emits outside. Because the first electrode 338 and the second electrode 316 can be distributed on all top surfaces and bottom surfaces, the current can spread uniformly, the wiring is easier, and the angle of light extraction of the LED chip 300 and 310 can be controlled easily.

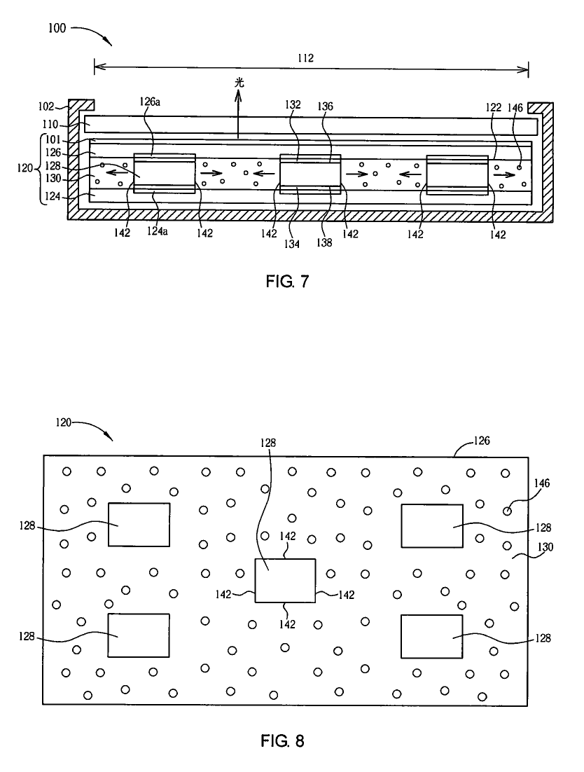

A light source module formed by the LED chips of the present application can be applied to various kinds of displays, illumination devices, and light-emitting devices, like the LB or the BLU of LCD. Referring to FIG. 7 and FIG. 8, FIG. 7 is a side view of an LCD 100 of a forth embodiment and FIG. 8 is a schematic view of a BLU 120 shown in FIG. 7. The LCD 100 includes a frame 102, an LCD panel 110, and a BLU 120, wherein the BLU 120 is a direct-type BLU located under the LCD panel 110. A surface of light extraction 122 of the BLU 120 is set to associate with a display region 112 of the LCD panel 110 for providing light employed by the LCD panel 110 for displaying image.

Referring to FIG. 7 and FIG. 8, the BLU 120 can include a first PCB 124, a second PCB 126 which is transparent, a plurality of LED chips 128, and an sealant 130 covering the plurality of LED chips 128. Each of the plurality of LED chips 128 can include a first electrode 132 and a second electrode 134 located on a top surface 136 and a bottom surface 134 of each of the plurality of LED chips 128 respectively. The second PCB 126 and the first PCB 124 are located on a top end and a bottom end of the LED chips 128 for controlling the switch thereof. The first electrode 132 and the second electrode 134 of each LED chip 128 are adjacent to and connect with a first connective end 126a of the second PCB 126 and a second connective end 124a of the first PCB 124 respectively by, for example, employing conductive glue for die mount and electrical connection, or direct contact with the circuit boards for electrical connection.

The LED chip 128 is located on the top surface of the first PCB 124 and at least includes a main light-emitting lateral surface 142. In this embodiment, the LED chip 128 can be the aforementioned LED chip including the patterned reflective layer or a side-emitting type LED. The main light-emitting lateral surface 142 of the LED chip 128 is perpendicular to the surface of light extraction 122 of the BLU 120. The top surface 136 of the LED chip 128 is located on the position facing the surface of light extraction 122. There is weaker light intensity or no light at the top surface 136 of the LED chip 128.

The sealant 130 can include any insulating materials which are transparent, solidifying, and moisture-proof, like epoxy. In addition, the sealant 130 can include a plurality of diffusing particles 146 which can change direction of the light to make the light emitted from the LED chip 128 out of the surface of light extraction 122 (same as the top surface of the sealant 130) of the BLU 120 uniformly.

Generally, an LED package is located on the lateral sides of a side-emitting LED type BLU. A light guide plate guides light to a surface of light extraction of the BLU. For the side-emitting LED type BLU, two ends of the BLU are brighter than the central part thereof because light sources are located on the lateral sides. Therefore, only the central part of the BLU can correspond to the LCD panel. The region providing light of the side-emitting LED type BLU occupies only 70% to 80% of the area of the BLU so the volume of the LCD can not be reduced effectively. The present application discloses a chip-scaled packaged module which the LED chip 128 is directly mounted on the first PCB 124 and the second PCB 126; not mounted the LED package on the circuit boards, the space of the package element like a cup, and the thickness of the BLU can be reduced sufficiently. For example, the thickness of the BLU 120 of the present application is about equal to the sum of the thicknesses of the first PCB 124, the second PCB 126, and the LED chip 128. Because of the reduced thickness of the BLU 120, the BLU 120 itself can be a planar light source so the chance of light consumed on the lateral surfaces of the BLU 120 can be reduced. Moreover, because the BLU 120 does not have to employ the package element like the cup, it can avoid absorbing or blocking the light by the cup and provide better optical performance.

In another aspect, the brightness of the lateral surfaces of the light-emitting device (the LED chip 128) is larger than that of the top surface thereof. The plurality of diffusing particles 146 of the sealant 130 can change the light emitting sideward to emit to the surface of light extraction 122 uniformly and penetrate the surface of light extraction 122. Therefore, the brightnesses of the periphery and the upside of the LED light source are about close. The problem of non-uniform brightness of the LED type BLU can be improved effectively, and there is enough light to be provided to the LCD panel 110.

It is noted that the first PCB 124 and the second PCB 126 can include various kinds of circuit board structures, preferably a soft PCB like a flexible PCB. Consequently, the present application can provide a flexible BLU to form more different kinds of displays. Besides, the first PCB 124 can support the LED chips 128 immediately. The surfaces of the first PCB 124 can include highly reflective materials like light color materials or metal materials to reflect light. Otherwise, the first PCB 124 can be transparent and has a reflector (not shown) located underneath to enhance the optical performance of the BLU 120. Furthermore, the LCD 100 can optionally include different kinds of optical film 101 based on the specification of the products. For example, a prism or a diffuser can be provided between the LCD panel 110 and the BLU 120 or a reflective layer can be provided in the frame 102 to further promote the display performance of the LCD 100.

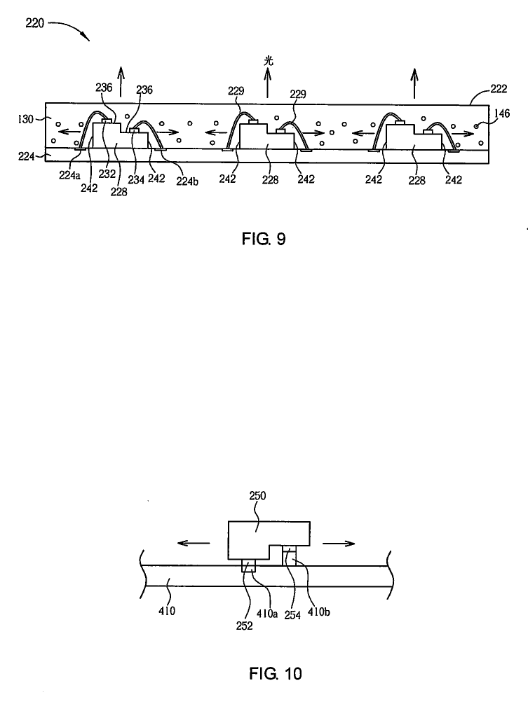

In addition, associating with different type LED chips, the present application can also employ other BLU structures. Referring to FIG. 9 which is a side view of a BLU 220 of a fifth embodiment of the present application, a first electrode 232 and a second electrode 234 of an LED chip 228 are located on a top surface 236 thereof. After fixing the LED chip 228 on a top surface of a first PCB 224, the first electrode 232 and the second electrode 234 can electrically connect with a first connective end 224a and a second connective end 224b of the first PCB 224 via a wire 229 respectively. Then, the sealant 130 having a plurality of diffusing particles 146 can cover each LED chip 228 to form a surface of light extraction 222 of the BLU 220.

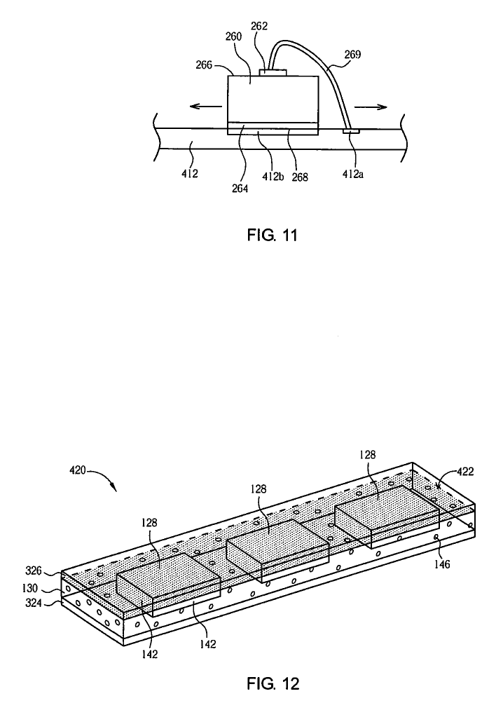

In this embodiment, similarly, each LED chip 228 primarily emits light through a main light-emitting lateral surfaces 242 perpendicular to the surface of light extraction 222. The light of weaker intensity or no light can emit from a top surface 236 of the LED chip 228 facing the surface of light extraction 222. For example, the LED chip 228 can include the aforementioned patterned reflective layer. However, it is noted that the application of the light-emitting devices of the present application are not limited to the aforementioned BLUs. Referring to FIG. 10 and FIG. 11 which show schematic views of the electrical connection of different kinds of the LED chips of the present application, when a first electrode 252 and a second electrode 254 of an LED chip 250 are located on the same side thereof, the first electrode 252 can be adjacent to and electrically connect with a first connective end 410a of a first PCB 254, and the second electrode 254 can be adjacent to and electrically connect with a second connective end 410b of the first PCB 254. Bumps or the conductive glue can be employed to form connection between the first electrode 252 and the first connective end 410a or the second electrode 254 and the second connective end 410b. Otherwise, direct contact can also be employed to form electrical connection therebetween. In this embodiment, the LED chip 250 can employ a transparent substrate and a patterned reflective layer located on a side of the transparent substrate close to or far away from the first electrode 252 and the second electrode 254. Therefore, a portion of the light of the LED 250 can penetrate the transparent substrate and emit to the upside of the LED chip 250. Most light emits toward the lateral surfaces of the LED chip 250.

Referring to FIG. 11, when a first electrode 262 and a second electrode 264 of an LED chip 260 are located on a top surface 266 and a bottom surface 268 thereof, the first electrode 262 can employ a wire 269 to electrically connect with a first connective end 412a of a first PCB 412 and the second electrode 264 can directly connect with a second connective end 412b of the first PCB 412.

Referring to FIG. 12 which shows a schematic view of an LB 420 of a sixth embodiment of the present application, a light source module of the LB 420 includes a similar structure of the aforementioned BLU 120. The LB 420 can include a strip type of PCB 324, a second PCB 326 which is transparent, the plurality of LED chips 128, and the sealant 130 covering the plurality of LED chips 128. The first electrode and the second electrode of the LED chip 128 are adjacent to and connect with the first connective end of a second PCB 326 and a second connective end (not shown) of the strip type of PCB 324 respectively. The main light-emitting lateral surfaces 142 of the LED chip 128 are perpendicular to a main surface of light extraction 422 of the LB 420, and the top surface of the LED chip 128 includes the patterned reflective layer (not shown) located on the position facing the main surface of light extraction 422. The open region of the patterned reflective layer allows light to penetrate and the reflective region thereof can reflect light to enhance lateral light-emitting of the LED chip 128 so the upside and the lateral sides thereof have uniform brightness.

The sealant 130 can protect the LED chips 128 and include the plurality of diffusing particles 146 additionally for a more uniform brightness thereof. As a result, the light generated from the LED chip 128 can uniformly emit to and penetrate through the main surface of light extraction 422 and the lateral surfaces of the LB 420. The light source module of the present application includes not only a slim structure but also a uniform brightness. It is noted that the light source module of the LB 420 can also adopt other package types, other methods of allocating the LED chips, and other methods of electrical connection, without limitation of the structure of the LB 420.

The LED chip of the present application primarily emits light through the lateral surfaces. The LED chip can emit the light of weaker intensity or no light through the top surface thereof. The sealant and the diffusing particles thereof can change the direction of light to make the light of the lateral sides of the LED chip penetrate the main surface of light extraction of the light source module. Therefore, the uniformity of the brightness of the light source module can be promoted. In addition, the present application also provides package of module in chip stage to largely reduce the volume of the light module.

It should be noted that the proposed various embodiments are not for the purpose to limit the scope of the application. Any possible modifications without departing from the spirit of the application may be made and should be covered by the application.

1. A light source module, comprising:
a first PCB;
a plurality of LED chips, located on a top surface of the first PCB and electrically connecting with the first PCB, each of the plurality of LED chips comprising:
a light-emitting structure; and
at least a patterned reflective layer, located on the light-emitting structure, wherein the patterned reflective layer comprises at least an opening and a reflective region, the opening occupies at most 20% of the area of the patterned reflective layer; and
an sealant, covering the plurality of LED chips, wherein a top surface of the sealant forms a main surface of light extraction of the light source module.

2. The light source module as described in claim 1, wherein the patterned reflective layer is a first electrode.

3. The light source module as described in claim 1, wherein each of the plurality of LED chips further comprises a reflective layer under the light-emitting structure.

4. The light source module as described in claim 1, wherein a light-emitting intensity of a top surface of each of the plurality of LED chips is lower than that of a lateral surface thereof.

5. The light source module as described in claim 1, further comprising a second PCB located on the plurality of LED chips, wherein the second PCB is a transparent PCB.

6. The light source module as described in claim 1, wherein each of the plurality of LED chips comprises a first electrode located on a top surface of the LED chip.

7. The light source module as described in claim 6, wherein the first electrode is a portion of the patterned reflective layer.

8. The light source module as described in claim 6, wherein the patterned reflective layer is located between the first electrode and the light-emitting structure.

9. The light source module as described in claim 6, wherein the first electrode is a patterned electrode, the patterned electrode and the patterned reflective layer comprise the same pattern.

10. The light source module as described in claim 1, wherein the opening comprises a circle opening or a grid opening.

11. The light source module as described in claim 1, wherein the light source module is an LB.

12. The light source module as described in claim 1, wherein the sealant comprises a plurality of diffusing particles.

13. The light source module as described in claim 1, wherein the light-emitting structure comprises:
a light-emitting stacked layer, located between the first PCB and the patterned reflective layer; and
a reflective layer, located between the light-emitting stacked layer and the first PCB.

14. The light source module as described in claim 1, wherein the light-emitting structure comprises a transparent substrate.

15. A BLU, comprising:
the light source module as described in claim 1; and
at least an optical film, located on the periphery of the light source module.

16. An LED chip, comprising:
a light-emitting structure, comprising a light-emitting stacked layer; and
at least a patterned reflective layer, located on the light-emitting structure, wherein the patterned reflective layer comprises at least an opening and a reflective region, the opening occupies at most 20% of an area of the patterned reflective layer.

17. The LED chip as described in claim 16, further comprising a reflective layer, located under the substrate or between the light-emitting stacked layer and the substrate.

18. The LED chip as described in claim 17, wherein the substrate is transparent.

19. The LED chip as described in claim 16, wherein the opening comprises a circle.
